(19) United States
(12) Patent Application Publication
(10) Pub. No.: US 2024/0234574 A9
(43) Pub. Date: Jul. 11, 2024

(54) FERROELECTRIC FIELD-EFFECT TRANSISTOR WITH HIGH PERMITTIVITY INTERFACIAL LAYER

(71) Applicant: The Regents of the University of California, Oakland, CA (US)

(72) Inventors: Sayeef Salahuddin, Walnut Creek, CA (US); Ava Jiang Tan, Berkeley, CA (US)

(21) Appl. No.: 18/546,807

(22) PCT Filed: Feb. 22, 2022
(86) PCT No.: PCT/US2022/017203

§ 371 Date: Aug. 17, 2023

Related U.S. Application Data
(60) Provisional application No. 63/153,180, filed on Feb. 24, 2021.

(51) Int. Cl. H01L 29/78; H10B 51/30

(52) U.S. Cl. CPC H01L 29/78391; H10B 51/30

(57) ABSTRACT

A ferroelectric field-effect transistor having an endurance exceeding 10¹² cycles is disclosed. The ferroelectric field-effect transistor includes a substrate, a source disposed over a first region of the semiconductor substrate, a drain disposed over a second region of the substrate, wherein the second region is spaced apart from the first region. The ferroelectric field-effect transistor includes a channel made of a semiconductor material within a third region of the substrate that is between the first region and the second region. The ferroelectric field-effect transistor further includes a gate stack having an interfacial layer disposed over the channel, wherein the interfacial layer has a permittivity that is greater than 3.9, and a layer of ferroelectric material disposed over the interfacial layer.

### RELATED APPLICATIONS

This application is a 35 USC 371 national phase filing of International application No. PCT/US2022/017203, filed Feb. 22, 2022, which claims the benefit of provisional patent application Ser. No. 63/153,180, filed Feb. 24, 2021, the disclosures of which are hereby incorporated herein by reference in their entireties.

### GOVERNMENT SUPPORT

This invention was made with government support under Grant Number N00014-20-1-2775 awarded by the Office of Naval Research. The government has certain rights in the invention.

### FIELD OF THE DISCLOSURE

This disclosure relates to nonvolatile memory and in particular to ferroelectric field-effect transistors that are utilized as nonvolatile memory elements that make up nonvolatile memory.

### BACKGROUND

A ferroelectric field-effect transistor (FeFET) is a type of field-effect transistor (FET) that includes a ferroelectric material within the structure of the FET. The ferroelectric material allows FeFETs to be used as non-volatile memory elements within nonvolatile memory integrated circuits.

Even though there has been much rekindled interest in ferroelectrics-based nonvolatile memories due to the discovery of complementary metal oxide semiconductor—compatible doped hafnium oxide (HfO₂) materials, one of the key roadblocks facing the development of FeFETs is endurance. For ferroelectric oxides thicker than 5 nm to 6 nm, bulk charge-trapping and interfacial layer breakdown—which are due to the large coercive fields associated with ferroelectric HfO₂ and therefore the larger write voltages needed to program FeFETs with thicker ferroelectric oxides—tend to cause premature device failure, with typical endurance metrics of 10⁴ cycles to 10⁶ cycles. For ferroelectric oxides thinner than 5 nm, hot electron-induced hole damage and channel/oxide interface degradation tend to be the key agents limiting device endurance.

Proposals to extend the cycling lifetime of FeFETs include interfacial oxide engineering, gate work function engineering, and modulating the material properties of the ferroelectric layer itself. In the present disclosure, a high-κ interfacial layer is combined with a thin ferroelectric film (˜4.5 nm). This is motivated by the observation that the endurance cycling is mostly limited by interfacial layer breakdown. In a metal-ferroelectric-metal capacitor configuration, cycling endurance metrics exceeding than 10¹⁰ cycles are routinely observed. The interfacial layer breakdown problem has been circumvented by fabricating a bottom-gate, channel last transistor, where an oxide semiconductor channel was grown directly on the ferroelectric material, producing an endurance cycling exceeding 10¹² cycles. Similarly, the fabrication of vertical three-dimensional negative-AND (NAND) ferroelectric thin film transistors utilizing indium zinc oxide as the semiconductor channel show a cycling endurance of up to 10⁸ cycles. Nonetheless, when crystalline silicon is used as the channel material, as is required for high-performance memory, formation of an interfacial layer is inevitable. As such, a need remains for FeFETs having crystalline silicon channels and an endurance cycling that exceeds 10¹² cycles.

### SUMMARY

A ferroelectric field-effect transistor having an endurance exceeding 10¹² cycles is disclosed. The ferroelectric field-effect transistor includes a substrate such as a semiconductor substrate, a source disposed over a first region of the semiconductor substrate, a drain disposed over a second region of the semiconductor substrate, wherein the second region is spaced apart from the first region. In some embodiments, the substrate is made of materials other than semiconductor materials. The ferroelectric field-effect transistor includes a channel made of semiconductor materials within a third region that is between the first region and the second region. The ferroelectric field-effect transistor further includes a gate stack having an interfacial layer disposed over the channel, wherein the interfacial layer has a permittivity that is greater than 3.9, and a layer of ferroelectric material disposed over the interfacial layer.

The present disclosure provides ferroelectric field-effect transistors (FeFETs) having crystalline silicon channels and an endurance exceeding 10¹² cycles. The FeFETs incorporate a high-κ interfacial layer of thermally grown silicon nitride (SiNₓ) and a thin 4.5 nm layer of zirconium-doped ferroelectric hafnium oxide (HfO₂) on a ˜30 nm silicon-on-insulator channel. The FeFETs show a ˜1 V memory window in a direct current sweep of ±2.5 V and can be programmed and erased with voltage pulses of V_{G}=±3 V at a pulse width of 250 ns. The FeFETs also have very good retention behavior. These results show that the high-κ interfacial layer substantially improves FeFET performance and reliability.

Those skilled in the art will appreciate the scope of the present disclosure and realize additional aspects thereof after reading the following detailed description in association with the accompanying drawings.

### BRIEF DESCRIPTION OF THE DRAWINGS

The accompanying drawing figures incorporated in and forming a part of this specification illustrate several aspects of the disclosure and, together with the description, serve to explain the principles of the disclosure.

FIG. 1A is a diagram of a silicon-on-insulator, gate-first ferroelectric field-effect transistor (FeFET).

FIG. 1B is a transmission electron microscopy (TEM) image of a 4.5 nm hafnium-zirconium oxide (HZO) gate stack with 8.2 Å silicon dioxide (SiO₂) interfacial layer.

FIG. 1C is a TEM of a 4.5 nm HZO gate stack with 1.5 nm SiNₓ interfacial layer.

FIG. 1D is a cyclic voltammetry comparison of gate stack with a SiO₂ interfacial layer to the gate stack with a nitrided interfacial layer, both taken at 100 kHz.

FIG. 2A is a graph showing I_{DVG} of a typical FeFET with a 4.5 nm HZO on a 1.5 nm nitrided interfacial layer. The FeFET is doubly-swept from 2.5 V at a drain bias of V_{D}=1 V.

FIG. 2B is a graph showing typical erase (ERS) state characteristics for the FeFET.

FIG. 2C is a graph showing typical program (PRG) state characteristics for the FeFET. Voltage magnitudes range from ±2.5 V to 3 V and pulse durations from 100 ns to 10 μs.

FIGS. 3A and 3B illustrate endurance stressing sequence and subsequent ferroelectric state determination waveforms used to characterize the FeFET that is structured according to the present disclosure.

FIG. 3C illustrates the endurance result on a representative FeFET up to 10¹² cycles.

FIG. 4 is a graph showing retention testing at room temperature (25° C.) and at elevated temperature (85° C.) for 10⁴ seconds. Gate read voltage is chosen to be the same at both testing conditions after correcting for the leftward V_{T} shift due to an effective substrate doping change at elevated temperature.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

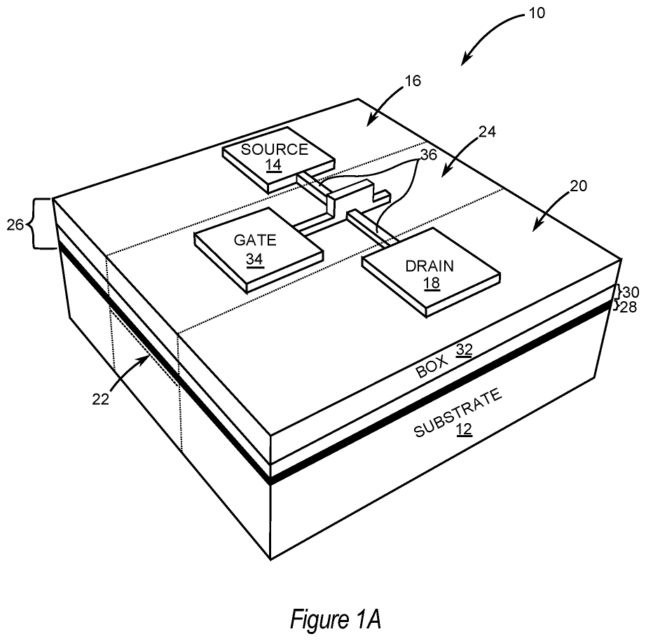

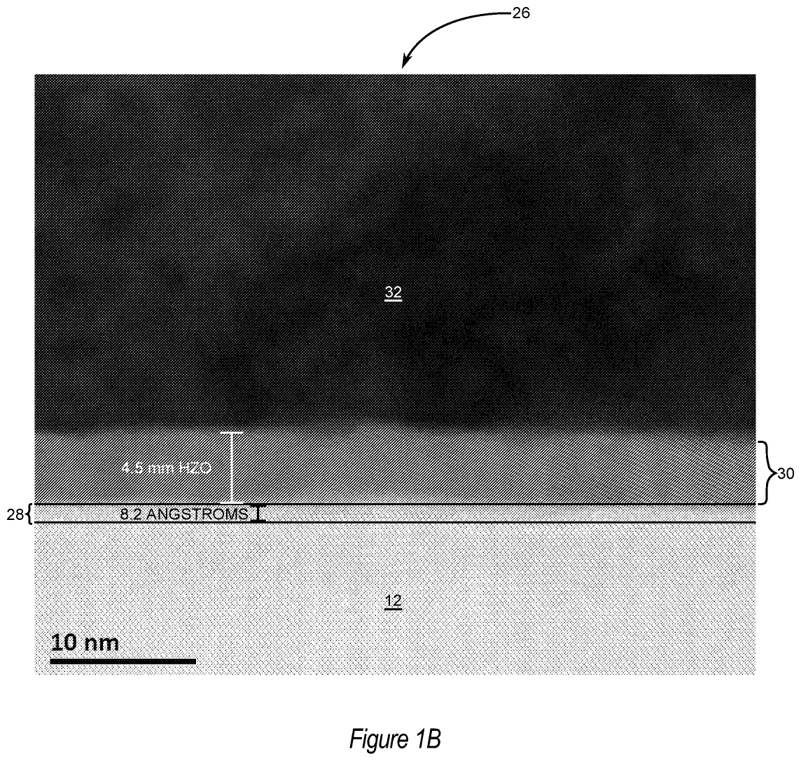

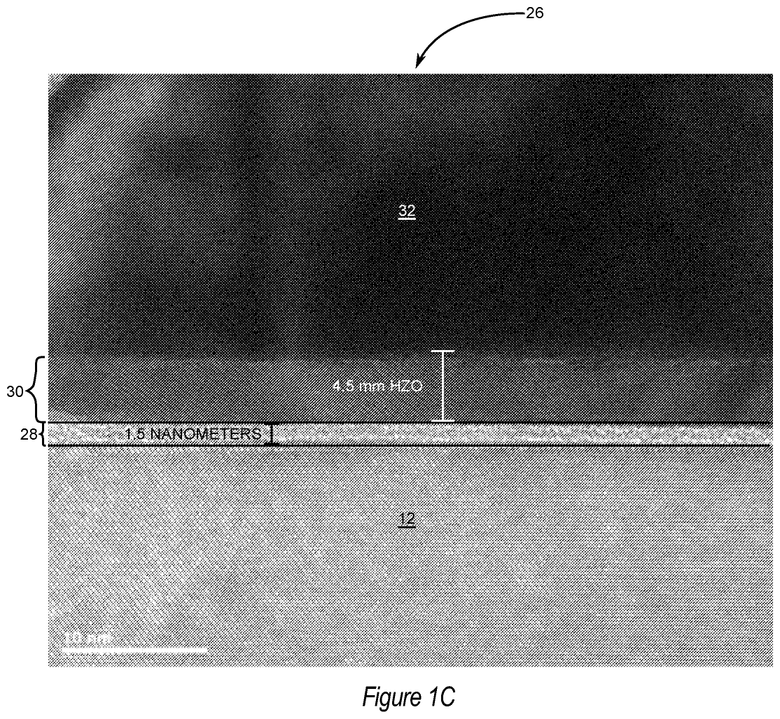

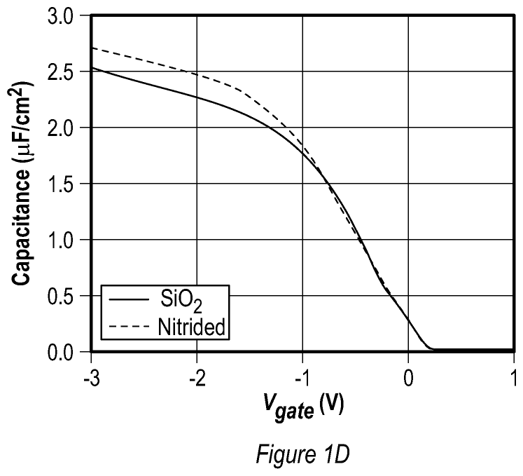

FIG. 1 depicts a ferroelectric field-effect transistor (FeFET) 10 that is structured in accordance with the present disclosure. The FeFET 10 has a substrate such as a semiconductor substate 12. A source 14 is disposed over the semiconductor substrate 12 within a first region 16. A drain 18 is disposed over the semiconductor substrate 12 within a second region 20 that is spaced apart from the first region 16. A channel 22 made of semiconductor materials resides within a third region 24 that is between the first region 16 and the second region 20. Further disclosed is a gate stack 26 having an interfacial layer 28 disposed over the channel 22 within the third region 24. A layer of ferroelectric material 30 is disposed over the interfacial layer 28. A buried oxide (BOX) layer 32 is disposed over the layer of ferroelectric material 30, and a gate structure 34 is disposed over the BOX layer 32 within the third region 24. In the exemplary embodiment of FIG. 1, the gate structure 34 extends over fins 36 of the source 14 and the drain 18.

The interfacial layer 28 is made of a high permittivity insulator material. At least some of the disclosed embodiments include FeFETs each having an interfacial layer 28 with permittivity >3.9 and a ferroelectric layer 30 made of binary materials such as doped HfO₂ or ScN or perovskite ferroelectric materials such as PbₓZr₁₋ₓTiO₃, PbTiO₃, BiFeO₃, and BaTiO₃ or its alloys with other species such as SrₓBa₁₋ₓTiO₃, deposited using atomic layer deposition, chemical vapor deposition, physical vapor deposition, or pulsed laser deposition. Other embodiments of the FeFET 10 each further include a silicon (Si) channel wherein the interfacial silicon dioxide (SiO₂) layer is doped with a species D that converts the SiO₂ into a high permittivity layer. Yet other embodiments of the FeFET 10 each further include a Si channel wherein the interfacial SiO₂ layer is doped with a species D that converts the SiO₂ into a high permittivity layer where D simultaneously acts as a dopant for the ferroelectric layer. Yet still other embodiments of the FeFET 10 further include an oxide channel material wherein an interfacial layer is directly deposited thereon. Further, other embodiments of the FeFET 10 have transistor structures wherein either the interfacial layer 28 or the ferroelectric layer 30 or both are placed on a planar surface or are conformally on a curved surface such as the fin of a finFET or the gate of a vertical transistor. Examples of D include N, La, Hf, and Zr.

Note that in some embodiments the channel 22 is made of or includes poly-crystalline silicon. In other embodiments, the channel 22 is made of or includes amorphous silicon. In other embodiments, the channel 22 is made of or includes oxide semiconductors. The oxide semiconductors may include but are not limited to indium gallium zinc oxide, indium tungsten oxide, indium oxide, and combinations thereof. In yet other embodiments, the channel 22 is made of or includes crystalline, poly-crystalline, or amorphous forms of carbon-based semiconductors. In some embodiments, the carbon-based semiconductors include carbon nanotubes and graphene and combinations thereof. In still other embodiments, the channel 22 is made of or includes crystalline, poly-crystalline, or amorphous forms of germanium. In yet other embodiments, the channel 22 is made of or includes crystalline, poly-crystalline, or amorphous forms of wide-bandgap materials. In some embodiments, the wide-bandgap materials comprise gallium nitride and gallium oxide and combinations thereof. In still other embodiments, the channel 22 is made up of or includes crystalline, poly-crystalline, or amorphous form of III-V materials. Suitable ones of the III-V materials include but are not limited to gallium arsenide, indium gallium arsenide, indium phosphorous, and combinations thereof. In yet other embodiments, the channel 22 comprises crystalline, poly-crystalline, or amorphous forms of two-dimensional semiconductors. In some embodiments, the two-dimensional semiconductors include chalcogenides.

Further note that in some embodiments, the interfacial layer 28 has a permittivity that is larger than 4. For example, the interfacial layer 28 is made of or includes high permittivity (k>4) insulators such as silicon nitride, hafnium oxide, zirconium oxide, silicon-oxynitride, hafnium oxynitride, zirconium oxynitride, lanthanum oxide, doped binary oxides, and combinations thereof. The doped oxides may include, but are not limited to, lanthanum- and zirconium-doped silicon dioxide and combinations thereof.

Also note that in some embodiments, the ferroelectric material 30 is made up or includes a binary material. In at least one embodiment, the binary material is hafnium oxide that in some embodiments is zirconium doped. In other embodiments, the hafnium oxide is doped with a dopant atom. In yet other embodiments, the dopant atom is selected from elements such as aluminum, yttrium, and silicon.

The disclosed high permittivity interfacial layer 28 substantially increases endurance beyond 10¹² cycles of highly scaled FeFETs 10 employed as ferroelectric memory devices having gate lengths (L_{G}) of less than 100 nm. This makes substantial impact in embeddable memory devices by potentially replacing various levels of cache memory by a non-volatile counterpart. This can have tremendous impact on a number of high-performance computing applications such as general-purpose servers, Al accelerators, reconfigurable field programmable gate arrays (FPGAs), and desktop computers.

In the context of interfacial layer breakdown, time-to-breakdown has an exponential relationship to the applied electric field in the interfacial layer 28. In other words, a mild decrease in the electric field can still lead to a substantial increase in the time-to-breakdown and therefore can slow the generation of traps that eventually counteract the ferroelectric hysteresis. For the same charge density, a high-κ interfacial layer reduces the electric field by the ratio of its permittivity to that of SiO₂. The choice of high-κ interfacial layer is a thermally grown silicon nitride. This high-κ interfacial layer provides a simple way to achieve an interfacial layer with a permittivity of ˜8. Thermally grown silicon nitride also has a comparable breakdown field to SiO₂. A 4.5 nm ferroelectric hafnium-zirconium oxide is chosen to suppress the effects of bulk charge trapping. This combination substantially improves the performance of the FeFET 10. In a direct current (DC) sweep, almost a 1 V memory window can be achieved with just ±2.5 V. Moreover, with bipolar stress pulsing at ±3 V, 250 ns, the endurance exceeds 10¹² cycles.

The structure of the FeFET 10 in accordance with the present disclosure is shown in FIG. 1A, and transmission electron microscopy images to compare its gate stack 26 incorporating a nitrided interfacial layer 28 against that of a baseline FET with an SiO₂ interfacial layer are shown in FIGS. 1B and 1C, respectively. In the process flow to realize the FeFET 10, the interfacial layer 28 formation step involves thermal nitridation of the silicon-on-insulator (SOI) substrate at 850° C. in ammonia (NH₃) ambient rather than a self-terminated chemical growth of SiO₂. As confirmed through transmission electron microscopy, the ferroelectric oxide thickness of both the control SiO₂ FeFET and the FeFET with a nitrided interfacial layer are the same, roughly 4.5 nm after 45 cycles of deposition. The interfacial layer thicknesses of the SiO₂ interfacial layer and nitrided interfacial layer are ˜8 Å and ˜1.5 nm, respectively.

FIG. 1D compares the cyclic voltammetry of the baseline FeFET with a SiO₂ interfacial layer to the cyclic voltammetry of the FeFET with a nitrided interfacial layer. Though the physical thickness of the gate stack of the latter is larger, the capacitance of the gate stack is larger. From the accumulation capacitance, the net effective oxide thickness of the nitrided sample is estimated to be roughly 1 Å smaller than the baseline sample using Synopsys TCAD. This allows an estimate for the effective κ of the interfacial layer as follows:

$${}^{κ} NIL = {}^{κ} {SiO}_{2} \times \frac{{}^{t} NIL}{{}^{t} baseline - δ {EOT}_{net}} = 3.9 \times \frac{1.5}{7.5} = 7.8$$

where ^{κ}NIL and ^{κ}SiO₂ indicate the κ values of the nitrided interfacial layer and SiO₂ interfacial layer, respectively; ^{t}NIL and ^{t}baseline indicate the physical thicknesses of the nitrided interfacial layer and SiO₂ interfacial layer, respectively; and δEOTₙₑₜ is the simulated effective oxide thickness difference between the two interfacial layers. This calculation indicates that roughly the entire volume of the interfacial layer has been nitrided. Therefore, the electric field in the interfacial layer is expected to be reduced by two times. Not only does this result in a substantial increase in the time to breakdown, but also the field reduction helps reduce the total voltage required to operate the FeFET, since a larger fraction of the applied voltage now drops across the ferroelectric layer rather than the interfacial layer.

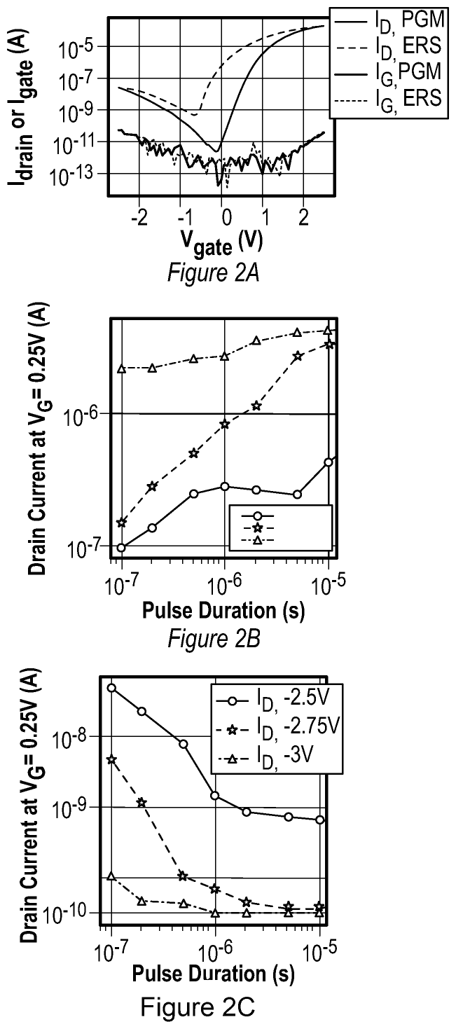

The DC hysteresis of the fabricated FeFET with a nitrided interfacial layer was first investigated. FIG. 2A shows results of a doubly swept I_{D}V_{G} curve. Nearly a 1 V memory window can be achieved with a ±2.5 V sweep. Compared to existing results, this is quite a low voltage requirement. For example, baseline FETs do not demonstrate any appreciable memory window at ±2.5 V. Nonetheless, the time to switch a given amount of polarization depends strongly on the applied voltage. Therefore, although the DC sweep is a good way of visualizing the hysteresis, it is important to also probe the high-speed switching behavior. FIGS. 2B and 2C show measured current at V_{G}=±0.25 V as a function of pulse width. The high current state is defined as the erase (ERS) state and the low current state as the program (PGM) state. Unsurprisingly, a strong dependence of the current on the applied voltage is observed. Below 1 μs, 2.5 V is not good enough to provide the current level observed in the DC hysteresis. As the voltage amplitude increases, the current increases, signifying switching of a larger amount of polarization. At a V_{G}=3 V, the current approaches the level seen in DC hysteresis, even at a pulse width of ˜100 ns. Similarly, for the PGM state, V_{G}=−3V brings the current level down to almost the level seen in the DC hysteresis at a pulse width of ˜250 ns. The asymmetry between PGM and ERS states is expected: accumulation of a thin SOI body requires a much larger voltage drop across the semiconductor. For a reasonably fast and symmetric operation, a pulse width of 250 ns and a gate voltage of V_{G}=±3V were chosen for endurance cycling.

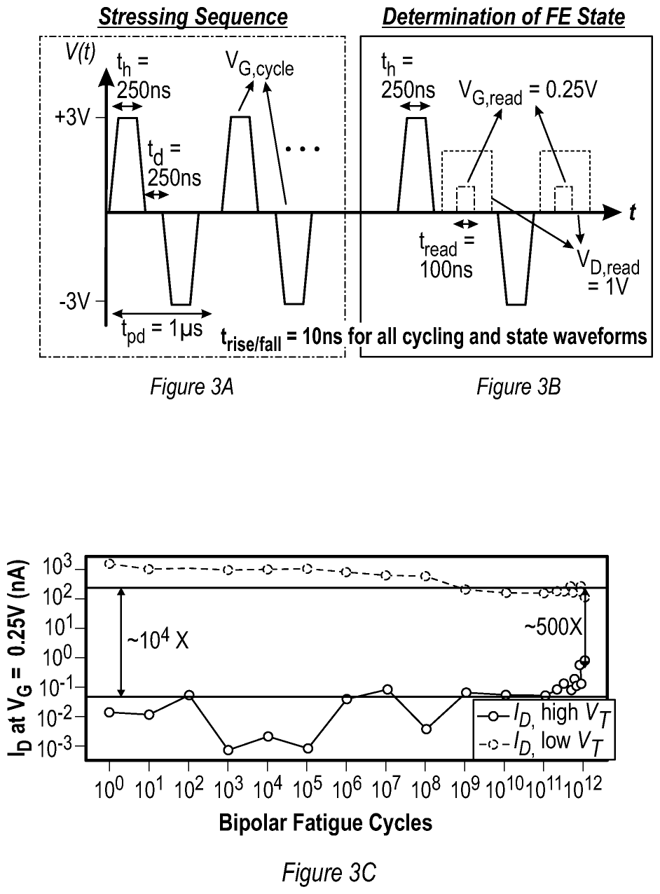

The endurance is quantified by measuring ±V_{T} after certain number of bipolar stress pulses. The ±V_{T} determination requires one to perform sweeps over a small voltage range, which typically takes ˜1 second to complete. On the other hand, fast reading is important. Note that, in a real application, the FeFET 10 will be read quickly. From charge pumping experiments, beyond several microseconds, charge trapping/de-trapping starts to manifest. These effects can in principle be quite complex and can arise from the interplay between traps with varying time constants. Therefore, slow sweeps to determine ±V_{T} are expected to be strongly influenced by these effects, artificially affecting the actual currents that are observed in an application when the FeFET 10 is read quickly. Due to these considerations, fast reading of the FeFET 10 was adopted to determine its state. The complete endurance testing protocol is detailed in FIG. 3A. During the stressing phase of the endurance cycling test, bipolar voltage pulses of ±3V, 250 ns are applied at the gate of the FeFET 10, with a 250 ns delay between sequential pulses to achieve a stressing period of 1 μs total in duration. Periodically throughout, a state determination test is conducted to evaluate the margin between the PGM and ERS states. For this, a short 100 ns read pulse is applied at the gate of the FeFET 10, after either the ERS or PGM pulse, after ramping and stabilizing the drain voltage at 1 V (see FIG. 3B), and the peak current value is determined to be the read current.

FIG. 3C shows the results of endurance testing. First, note that the high and low current levels are very similar to those measured from a DC sweep. This indicates both that the FeFET 10 is switched properly with the PGM/ERS pulses and that the fast read can read off the state. Note also that there is a small uncertainty about the exact current level for the low current state due to the fast read operation. Nonetheless, even considering the largest values measured for the low current state prior to 10¹¹ cycles, an I_{ERS}/I_{PGM} of larger than 10⁴ is achieved. Interestingly, the FeFET 10 does not show any rapid degradation after 10⁴ cycles to 10⁶ cycles. Rather, the high current level, which is associated with the ERS state, shows a slow degradation up to 10¹² cycles. On the other hand, the low current level, which is associated with the PGM state, fluctuates a little bit but remains low enough to maintain a margin of 10⁴ I_{ERS}/I_{PGM} until ˜5×10¹¹ cycles. Beyond that point, a sudden increase is observed, but the FeFET 10 maintains greater than two orders of magnitude of current level separation up to 10¹² cycles. Also note that after 10¹¹ switching cycles, polarization fatigue in the ferroelectric material may ensue. Therefore, the degradation seen beyond 5×10¹¹ cycles can result from fatigue, exacerbated by the fact that the PGM pulse, which is already at a disadvantage due to the SOI body, is not able to switch enough polarization, thereby causing the low current level to increase abruptly. Distinguishing between polarization fatigue and other degradation mechanisms at this extent of endurance cycling may be determined with additional investigation.

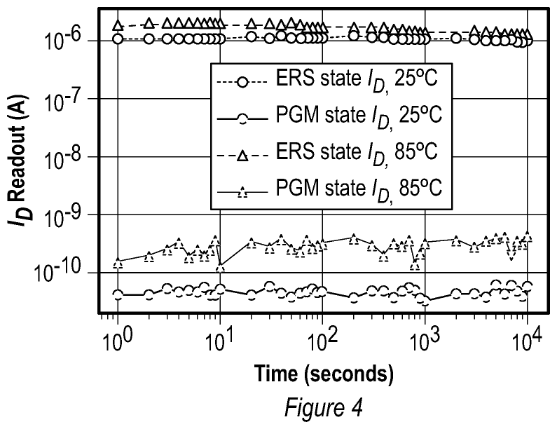

Also, as shown in FIG. 4, memory retention looks unaffected for a testing duration of 10⁴ seconds for both the PGM and ERS states. At 85° C., both the high and low current levels increase, with the low current increasing more as expected. But in general memory retention looks robust. Thus, despite relatively lower voltage operation and very large endurance, there is no discernible effect on the retention behavior.

Further still, the FeFET 10 may be employable as a memory device with an engineered high-κ interfacial layer shows greater than 10¹² endurance cycles at a relatively small PGM/ERS voltage of V_{G}=±3 V and pulse width of 250 ns. Endurance of greater than 10¹² cycles is expected to open a large area of applications for ferroelectric memory devices, including being used as persistent memory for certain use cases. Additional optimization of the interfacial layer 28 and ferroelectric layer 30 will allow for further reduction in the operating voltage to below 2 V while maintaining and/or even enhancing the endurance behavior.

Those skilled in the art will recognize improvements and modifications to the present disclosure. All such improvements and modifications are considered within the scope of the concepts disclosed herein.

1. A ferroelectric field-effect transistor comprising:
a substrate;
a source disposed over a first region of the substrate;
a drain disposed over a second region of the substrate, wherein the second region is spaced apart from the first region;
a channel comprised of a semiconductor material within a third region that is between the first region and the second region; and
a gate stack comprising:
an interfacial layer disposed over the channel, wherein the interfacial layer has a permittivity that is greater than 3.9; and
a layer of ferroelectric material disposed over the interfacial layer.

2. The ferroelectric field-effect transistor of claim 1 wherein the channel comprises crystalline silicon.

3. The ferroelectric field-effect transistor of claim 1 wherein the channel comprises poly-crystalline silicon.

4. The ferroelectric field-effect transistor of claim 1 wherein the channel comprises amorphous silicon.

5. The ferroelectric field-effect transistor of claim 1 wherein the channel comprises oxide semiconductors.

6. The ferroelectric field-effect transistor of claim 5 wherein the oxide semiconductors comprise indium gallium zinc oxide, indium tungsten oxide, indium oxide, and combinations thereof.

7. The ferroelectric field-effect transistor of claim 1 wherein the channel comprises crystalline, poly-crystalline, or amorphous forms of carbon-based semiconductors.

8. The ferroelectric field-effect transistor of claim 7 wherein the carbon-based semiconductors comprise carbon nanotubes.

9. The ferroelectric field-effect transistor of claim 7 wherein the carbon-based semiconductors comprise graphene.

10. The ferroelectric field-effect transistor of claim 1 wherein the channel comprises crystalline, poly-crystalline, or amorphous forms of germanium.

11. The ferroelectric field-effect transistor of claim 1 wherein the channel comprises crystalline, poly-crystalline, or amorphous forms of wide-bandgap materials.

12. The ferroelectric field-effect transistor of claim 11 wherein the wide-bandgap materials comprise gallium nitride, gallium oxide, and combinations thereof.

13. The ferroelectric field-effect transistor of claim 1 wherein the channel comprises crystalline, poly-crystalline, or amorphous forms of III-V materials.

14. The ferroelectric field-effect transistor of claim 13 wherein the III-V materials are gallium arsenide, indium gallium arsenide, indium phosphorous, and combinations thereof.

15. The ferroelectric field-effect transistor of claim 1 wherein the channel comprises crystalline, poly-crystalline, or amorphous form of two-dimensional semiconductors.

16. The ferroelectric field-effect transistor of claim 15 wherein the two-dimensional semiconductors are chalcogenides.

17. The ferroelectric field-effect transistor of claim 1 wherein the interfacial layer has a permittivity that is larger than 4.

18. The ferroelectric field-effect transistor of claim 17 wherein the interfacial layer comprises high permittivity (k>4) insulators.

19. The ferroelectric field-effect transistor of claim 18 wherein the high permittivity (k>4) insulators comprise silicon nitride, hafnium oxide, zirconium oxide, silicon-oxynitride, hafnium oxynitride, zirconium oxynitride, lanthanum oxide, other doped binary oxides, and combinations thereof.

20. The ferroelectric field-effect transistor of claim 19 wherein the doped oxides comprise lanthanum- and zirconium-doped silicon dioxide and combinations thereof.

21. The ferroelectric field-effect transistor of claim 1 wherein the ferroelectric material comprises a binary material.

22. The ferroelectric field-effect transistor of claim 21 wherein the binary material is hafnium oxide.

23. The ferroelectric field-effect transistor of claim 22 wherein the hafnium oxide is zirconium doped.

24. The ferroelectric field-effect transistor of claim 22 wherein the hafnium oxide is doped with a dopant atom.

25. The ferroelectric field-effect transistor of claim 24 wherein the dopant atom is from the group consisting of aluminum, yttrium, and silicon.

26. The ferroelectric field-effect transistor of claim 21 wherein the binary material is scandium nitride.

27. The ferroelectric field-effect transistor of claim 1 wherein the ferroelectric material comprises a perovskite ferroelectric material.

28. The ferroelectric field-effect transistor of claim 1 wherein the interfacial layer is configured to provide an endurance of greater than 10¹² cycles.

29. A method of fabricating a ferroelectric field-effect transistor comprising:
providing a substrate;
disposing a source over a first region of the substrate;
disposing a drain over a second region of the substrate, wherein the second region is spaced apart from the first region forming a channel between the source and the drain;
forming a gate stack by:
disposing an interfacial layer over the channel, wherein the interfacial layer has a permittivity that is greater than 3.9; and
disposing a layer of ferroelectric material over the interfacial layer.

30. The method of fabricating the ferroelectric field-effect transistor of claim 29 wherein the channel comprises crystalline silicon.

31. The method of fabricating the ferroelectric field-effect transistor of claim 29 wherein the interfacial layer has a permittivity that is larger than 4.0.

32. The method of fabricating the ferroelectric field-effect transistor of claim 29 wherein disposing the interfacial layer comprises thermally growing silicon nitride onto the channel.

33. The method of fabricating the ferroelectric field-effect transistor of claim 29 wherein the ferroelectric material comprises a binary material.

34. The method of fabricating the ferroelectric field-effect transistor of claim 33 wherein the binary material is hafnium oxide.

35. The method of fabricating the ferroelectric field-effect transistor of claim 34 wherein the hafnium oxide is zirconium-doped.

36. The method of fabricating the ferroelectric field-effect transistor of claim 29 wherein the binary material is scandium nitride.

37. The method of fabricating the ferroelectric field-effect transistor of claim 29 wherein the ferroelectric material comprises a perovskite material.

38. The method of fabricating the ferroelectric field-effect transistor of claim 29 wherein the interfacial layer is configured to provide an endurance of greater than 10¹² cycles.

39. The method of fabricating the ferroelectric field-effect transistor of claim 29 wherein the channel comprises poly-crystalline silicon.

40. The method of fabricating the ferroelectric field-effect transistor of claim 29 wherein the channel comprises amorphous silicon.

41. The method of fabricating the ferroelectric field-effect transistor of claim 29 wherein the channel comprises oxide semiconductors.

42. The method of fabricating the ferroelectric field-effect transistor of claim 41 wherein the oxide semiconductors comprise indium gallium zinc oxide, indium tungsten oxide, indium oxide, and combinations thereof.

43. The method of fabricating the ferroelectric field-effect transistor of claim 29 wherein the channel comprises crystalline, poly-crystalline, or amorphous forms of carbon-based semiconductors.

44. The method of fabricating the ferroelectric field-effect transistor of claim 43 wherein the carbon-based semiconductors comprise carbon nanotubes.

45. The method of fabricating the ferroelectric field-effect transistor of claim 43 wherein the carbon-based semiconductors comprise graphene.

46. The method of fabricating the ferroelectric field-effect transistor of claim 29 wherein the channel comprises crystalline, poly-crystalline, or amorphous forms of germanium.

47. The method of fabricating the ferroelectric field-effect transistor of claim 29 wherein the channel comprises crystalline, poly-crystalline, or amorphous forms of wide-bandgap materials.

48. The method of fabricating the ferroelectric field-effect transistor of claim 47 wherein the wide-bandgap materials comprise gallium nitride, gallium oxide, and combinations thereof.

49. The method of fabricating the ferroelectric field-effect transistor of claim 29 wherein the channel comprises crystalline, poly-crystalline, or amorphous form of III-V materials.

50. The method of fabricating the ferroelectric field-effect transistor of claim 49 wherein the III-V materials are gallium arsenide, indium gallium arsenide, indium phosphorous, and combinations thereof.

51. The method of fabricating the ferroelectric field-effect transistor of claim 29 wherein the channel comprises crystalline, poly-crystalline, or amorphous form of two-dimensional semiconductors.

52. The method of fabricating the ferroelectric field-effect transistor of claim 51 wherein the two-dimensional semiconductors are chalcogenides.

53. The method of fabricating the ferroelectric field-effect transistor of claim 29 wherein the interfacial layer comprises high permittivity (k>4) insulators.

54. The method of fabricating the ferroelectric field-effect transistor of claim 53 wherein the high permittivity (k>4) insulators comprise silicon nitride, hafnium oxide, silicon-oxynitride, hafnium oxynitride, lanthanum oxide, doped binary oxides, and combinations thereof.

55. The method of fabricating the ferroelectric field-effect transistor of claim 54 wherein the doped oxides comprise lanthanum- and zirconium-doped silicon dioxide and combinations thereof.
